(19) United States
(12) Patent Application Publication
(10) Pub. No.: US 2025/0171888 A1
(43) Pub. Date: May 29, 2025

(54) METHOD FOR PRODUCING AN OPTICAL LAYER SYSTEM, AND AN OPTICAL LAYER SYSTEM PRODUCED THEREWITH

(71) Applicant: FHR ANLAGENBAU GMBH, Ottendorf-Okrilla (DE)

(72) Inventors: Beate BERGK, Dresden (DE); Rocco LIEBSCHNER, Dresden (DE); Mark RUDIN, Dresden (DE)

(73) Assignee: FHR ANLAGENBAU GMBH, Ottendorf-Okrilla (DE)

(21) Appl. No.: 18/843,019

(22) PCT Filed: Jun. 15, 2022
(86) PCT No.: PCT/EP2022/066440

§ 371 Date: Aug. 30, 2024

(30) Foreign Application Priority Data
Mar. 1, 2022 (EP) 22159391.6

(51) Int. Cl. C23C 14/14; C23C 14/00; C23C 14/54; C23C 16/24; C23C 16/28; G02B 5/28

(52) U.S. Cl. CPC C23C 14/14; C23C 14/0057; C23C 14/54; C23C 16/24; C23C 16/28; G02B 5/289

(57) ABSTRACT

Method for producing an optical layer system that includes a multiplicity of layers arranged on a substrate, where part of the layers has a high refractive index n_{H}, another part has a low refractive index n_{L} and a further part has a middle refractive index n_{M}, where n_{H}>n_{M}≥n_{L} and the layers having different refractive indices have an alternating stacked arrangement. The layers of the optical layer system are deposited onto a substrate by a selected coating method from an identical material which is hydrogenated amorphous silicon (a-Si:H) or hydrogenated germanium (Ge:H), where a refractive index and an extinction coefficient of each layer of the multiplicity of layers of the layer system are adjusted by a regulation of process parameters of the selected coating method.

The invention relates to a method for producing an optical layer system which consists of a multiplicity of layers.

The invention likewise relates to an optical layer system which is produced by the method of the invention and comprises a multiplicity of layers arranged on a substrate, where one part of the layers has a high refractive index n_{H} and another part of the layers has a low refractive index n_{L}, and also a further part of the layers has a middle refractive index n_{M}, where n_{H}>n_{M}≥n_{L} and where the layers having different refractive indices have an alternating stacked arrangement.

Optical layer systems, particularly optical filters, examples being bandpass filters for time-of-flight (ToF) spectroscopy for facial or gesture recognition, or LIDAR for optical distance and speed measurements, for the near infrared (NIR) or infrared (IR) range, are typically manufactured from two different optical materials. These materials consist, for example, of a-Si:H as high-index material and SiO: as low-index material.

In a typical gesture recognition system, a light source emits near infrared light to a user. An image sensor captures the emitted light reflected by the user, to provide a 3D image of the user. A processing system then analyzes the 3D image, to recognize a gesture made by the user.

An optical filter, specifically a bandpass filter, is used in order to transmit the emitted light to the image sensor, while the ambient light is substantially blocked. The optical filter therefore serves to screen out the ambient light. An optical filter is therefore needed which has a narrow pass band in the wavelength range in the near infrared, i.e., for example, from 800 nm to 1100 nm. Furthermore, the optical filter must have a high transmission level/transmittance within the pass band and a high blocking level or stop band outside the pass band, with the transmission in the stop band ideally tending to zero.

Conventionally the optical filter comprises two bandpass filters arranged on opposite surfaces of a substrate. The pass bands of the bandpass filters here are harmonized with one another in such a way that the pass band of the bandpass filter on the reverse of the substrate envelops the pass band of the filter on the front of the substrate. At the same time the pass bands of the filters are harmonized with one another so as to produce an antireflection effect. The bandpass filter on the reverse of the substrate therefore blocks the wavelengths outside the pass band of the bandpass filter on the front of the substrate. Each of the filters consists of layers of high refractive index and layers of low refractive index, stacked alternately. In general, various oxides are used for the layers of high refractive index and for the layers of low refractive index, such as titanium dioxide (TiO₂), niobium pentoxide (Nb₂O₅), tantalum pentoxide (Ta₂O₅) or silicon dioxide (SiO₂).

U.S. Pat. No. 9,945,995 B2 discloses an optical filter of this kind, having a pass band which overlaps at least partly with a wavelength range from 800 nm to 1100 nm. The optical filter comprises a filter stack consisting of hydrogenated silicon layers as high-index layer and of layers of lower refractive index, which are stacked alternately. The hydrogenated silicon layers each have a refractive index of more than 3 over the wavelength range from 800 nm to 1100 nm and an extinction coefficient of less than 0.0005 over the wavelength range from 800 nm to 1100 nm. The material with lower refractive index is a dielectric material, typically an oxide. Suitable materials with lower refractive index are silicon dioxide (SiO₂), aluminum oxide (Al₂O₃), titanium dioxide (TiO₂), niobium pentoxide (Nb₂O₅), tantalum pentoxide (Ta₂O₅) and mixtures thereof, i.e., mixed oxides.

Likewise known from U.S. Pat. No. 9,989,684 B2 is an optical interference filter having improved transmission in the pass band of the filter. This interference filter disclosed comprises a stack of multiple layers, with at least one layer consisting of hydrogenated amorphous silicon having a high refractive index and at least one layer consisting of one or more dielectric materials having a lower refractive index than the refractive index of the hydrogenated amorphous silicon.

In order to improve the power of an optical filter in, for example, a gesture recognition system, it is desirable to reduce the number of layers, the overall coating thickness, and the shifting of the wavelengths with change in the angle of incidence (AOI). There ought, moreover, to be minimum transmission in the region of the stop bands outside the pass band. Wavelength shifting in the sense of the invention refers to the shifting of the pass band of a filter, and this shifting ought to be as small as possible, so that virtually the same filter properties are present at different viewing angles onto the filter. One approach at an improvement in this respect is to use a material having a higher refractive index than that possessed by conventional oxides over the wavelength range of interest for the layers with high refractive index, as is disclosed, for example, in U.S. Pat. No. 9,945,995 B2. As well as a higher refractive index, the material must also have a lower extinction coefficient over the wavelength range of interest, in order to provide a high transmission level within the pass band. To date, however, different materials have always been used for the layers having different refractive indices.

A substantial disadvantage of using different materials for such optical filters is that these materials are generally deposited onto a substrate within the same coating unit. There is a need to use different coating sources and coating processes, with different process gases being used for each coating source. In the case of a switch in coating sources and hence in process gases, this entails long purging processes, leading to very long process times. The methods for producing high-quality optical interference filters and optical layer systems with numerous different layers and layer materials are also complicated and protracted.

It is therefore an object of the present invention to specify a method for producing an optical layer system that does not have the disadvantages of the prior art, such as, for example, long purge times between the layer depositions. With the method it ought to be possible simply to produce an optical layer system, and more particularly the process times ought to be short, so that a high quantity of end products produced by the method can be realized in consistent quality.

It is likewise an object of the present invention to specify an optical layer system which has optimal layer properties for the sphere of use and which can be produced in a highly reproducible and efficient way.

The object is achieved by a method for producing an optical layer system consisting of a multiplicity of layers in accordance with independent claim 1 of the patent.

In the method of the invention for producing an optical layer system which consists of a multiplicity of layers, the layers of the optical layer system are deposited onto a substrate by means of a selected coating method from an identical material, which is hydrogenated amorphous silicon (a-Si:H) or hydrogenated germanium (Ge:H), where a refractive index and an extinction coefficient of each layer of the multiplicity of layers of the layer system are adjusted by means of a regulation of process parameters of the selected coating method.

A particular advantage is that in the production method of the invention for the optical layer system, irrespective of the coating method, only a single material is deposited, namely a-Si:H:x or Ge:H:x, and the optical properties, such as the refractive index and the extinction coefficient of each layer can be adjusted merely by the regulation of one typical process parameter or two or more typical process parameters for the selected coating method. Represented by x may be further process gases such as nitrogen (N₂) or chlorine (Cl₂). The production method is therefore very simple, shorter than in the prior art, owing to the absence of the need for purging processes between different layer materials and process gases, and therefore more cost-efficient.

In one embodiment of the method of the invention, the coating method is a sputtering process, where the sputtering process takes place either reactively by means of a reactive gas mixture of argon (Ar), and/or krypton (Kr), and/or helium (He), and/or xenon (Xe), and hydrogen (H₂), or the sputtering of silicon takes place by means of Ar, Kr, He and/or Xe and the layers of the layer system are hydrogenated to a-Si:H or Ge:H by means of a plasma source and/or ion source, or the sputtering process is carried out as a combination of reactive sputtering and of the plasma source and/or ion source used, where the refractive index and the extinction coefficient of each individual a-Si:H:x or Ge:H:x layer of the layer system are adjusted via a ratio of hydrogen to Ar, Kr, He and/or Xe. A further layer component, which in one embodiment of the method may be present, but does not have to be present, is represented by x. This applies to all selectable coating processes.

Where a sputter technology is selected as coating method, there are a number of production variants for the production of a-Si:H and/or Ge:H. In one variant the sputter process takes place reactively, i.e., a reactive gas mixture, preferably of argon and hydrogen, is used. For other layer compositions, such as a-Si:H:N, for example, nitrogen or oxygen may also be used as reactive gases for the sputter process. The use of nitrogen (N) or oxygen (O₂) has the advantage that in this way it is possible to correct the layer stress of the deposited layer due to the greater ionic/atomic radius in relation to the hydrogen, in the direction of compressive stress. As a result it is possible to reduce or correct tensile stresses in the a-Si:H and/or Ge:H layers.

In a further variant, the sputter process may take place with argon and/or krypton and/or helium and/or xenon in such a way that only a silicon or germanium layer of subnanometer thickness is deposited by sputtering, and in an aftertreatment step is hydrogenated or nitrided or oxidized or oxynitrided or hydronitrided with an ion source and/or plasma source. These two process steps are repeated iteratively until the desired layer thickness is reached. In the aftertreatment step, the substrate with the metallically sputtered layer is passed through a plasma, which is generated by a plasma source and/or ion source. The source may for example be an ICP (inductive coupled plasma) source.

A third variant represents a combination of the two aforesaid variants. The reactive gas is used not only in the sputtering process, in the deposition of a layer of subnanometer thickness, but also in the aftertreatment employing a plasma source and/or ion source. Through the choice of the gas flow, the ratio of, for example, argon to the reactive gas in the sputter source or in the plasma source and/or ion source, the powers of the sputter source or of the plasma source and/or ion source, and also the temperature of the surface/substrates to be coated, the eventual stoichiometry and structure of the a-Si:H:x or Ge:H:x layer is established. These then determine the optically relevant variables, such as the refractive index and the extinction coefficient, of each individual layer of the optical layer system.

The relationship between the optical properties for the layers with high, middle and low refractive index and the process variables of the sputter process is implemented experimentally in advance of the layer production. The individual process steps in the deposition of the optical layer system are then based on these studies. A key regulating variable in the production of a-Si:H:x and Ge:H:x layers is the ratio of hydrogen to reactive gas, such as argon, with the density of material and therefore the refractive index falling as the fraction of hydrogen in the reactive gas becomes higher. For the adjusted ratios of argon to hydrogen, values of 1:2 to 5:1 are established, more particularly in the range from 1:3 to 4:1. The ratios of the gas mixtures to one another are selected such that the refractive index can be established therewith in a range relevant for the filter, so that, for the cavities of the filter to be produced, the refractive index realized can be as high as possible and at the same time the extinction coefficient realized can be as low as possible. On this basis, the refractive index of the high-index layer of the filter stack is established at a higher level, with the associated impairment of the extinction coefficient being accepted. In the same way, for the low-index layer of the filter stack, the refractive index established is as small as possible and a minimum extinction coefficient is observed.

The deposition of a-Si:H:N is one example of a filter stack layer to be deposited. With the method of the invention it is likewise possible to generate layers of a-Si:H:N:Cl, a-(Si,Ge):H, a-(Si,Ge):H:N and/or a-(Si,Ge):H:N:Cl. Further combinations of hydrogenated silicon and/or germanium and reactive gases are possible and are not confined to the abovementioned combinations.

In another embodiment of the method of the invention, the reactive gas mixture is argon and nitrogen, Na, or argon and oxygen, O₂. The choice of reactive gas mixture depends on the layer composition to be deposited. This has the advantage that it is possible therewith to correct the layer stress due to the larger ionic or atomic radius, in relation to the hydrogen, in the direction of compressive stress. As a result it is possible to reduce or correct tensile stresses in the a-Si:H or Ge:H layers.

In another embodiment of the method of the invention, the coating method is a chemical vapor deposition (CVD) process, where the CVD process takes place either with plasma enhancement or catalytically or thermally by means of an evaporator unit and a plasma source, where the refractive index and the extinction coefficient of each a-Si:H or Ge:H layer of the layer system are adjusted by means of a gas flow regulation via a ratio of silanes or germanes and hydrogen or of a power of the evaporator unit and the plasma source. By the gas flow regulation is meant either that an absolute gas flow of the silanes or germanes or of the hydrogen is adjusted or that one of the gases, silanes or germanes or hydrogen, is held constant and the other respective gas is regulated, or that gas mixtures of the two gases are prepared. The stoichiometry of the respective filter layers may therefore be adjusted by means of the gas flows of the silane gas or germane gas and of the hydrogen and also the ratios thereof to one another (partial gas flows) in a gas mixture of the plasma source and/or of a power of the evaporator unit and/or of the plasma source.

Where chemical vapor deposition (CVD) is selected as coating process, there are different variants of the CVD technology that can be used for the production of a-Si:H:x or Ge:H:x layers, such as plasma-enhanced CVD (PECVD), or catalytic or thermal CVD. The optical properties of the deposited a-Si:H:x or Ge:H:x layers of the layer system are adjusted by a different ratio of the reactive gases to one another. Specifically the ratio of H₂ to silane or germane is adjusted by a gas flow regulation in such a way that the desired optical properties are attained. The relationship between process gas ratio, process gas flow, substrate temperature, which is typically between 160-200° C., optionally the power of a plasma source, which is driven either by means of direct voltage or in high-frequency form, and the refractive index and the extinction coefficient is ascertained in advance experimentally for the different layers and desired layer properties. These process variables are then employed for the generation of the optical layer system.

With this coating method it is also possible to produce a-Si:H:N layers, by adding nitrogen as third reactive gas. It is also possible to generate a-Si:H:N:Cl, a-(Si,Ge):H, a-(Si,Ge):H:N and/or a-(Si,Ge):H:N:Cl layers, by adding further process gases and/or by using germane instead of silicon. Further combinations of hydrogenated silicon and germane and reactive gases are possible and are not confined to the abovementioned combinations.

In order to improve the layer properties, it is possible with this coating method to carry out a heat treatment of the layer or of the whole optical layer system under reduced pressure or an argon atmosphere. Typical temperatures of an aftertreatment step (post-process annealing) are 100° C.-370° C., preferably 200° C.-285° C., for 1 min to 60 min, preferably 10 min.

In the case of a thermal CVD process, the a-Si:H:x or Ge:H:x layers of the optical layer system are deposited with different stoichiometries and therefore optical properties by means of an evaporator unit for silicon in combination with a plasma source (assist source), the plasma source being operated with a mixture of argon and hydrogen. To generate nitrides, oxides, oxynitrides or hydronitrides, the corresponding gases can also be mixed in the process. The adjustment of the refractive index and of the extinction coefficient of the layers of the optical layer system that are deposited by means of thermal CVD process is accomplished through the adjustment of the absolute gas flow and a ratio, ascertained in advance of the deposition, of the partial gas flows (such as silanes, germanes, hydrogen, etc.) in the respective gas mixture in the ion source and of the powers of the evaporator unit and the plasma source. Hence for each layer the stoichiometry can be adjusted and therefore the optical behavior controlled. The aim is typically for substrate temperatures at which the layers are deposited of 100° C.-300° C., preferably 140° C.-240° C.

In prior trials, determinations are made of the optimal process parameters, for the respective arrangement of evaporator, substrate to be coated and plasma source, for a layer to be deposited with high, low or middle refractive index. Using these known data it is then possible to deposit layers of the optical layer system.

In another, further embodiment of the method of the invention, the coating method is an electron beam evaporation process in conjunction with an ion source, where the refractive index and the extinction coefficient of each a-Si:H:x or Ge:H:x layer of the layer system are adjusted by means of an establishment of an absolute gas flow and/or a ratio of partial gas flows in a gas mixture of the ion source and of a power of an evaporator unit and/or the ion source. By the absolute gas flow is meant the summated gas flow of the doping gases, such as hydrogen (H₂) and/or nitrogen (N₂) and/or chlorine (Cl₂), and/or of a mixture of these doping gases. The individual doping gases may also be regulated in partial gas flows.

Where the coating method selected is an evaporation process for the deposition of the a-Si:H:x or Ge:H:x layers with different stoichiometries and hence optical properties, an evaporator unit for silicon or germanium, respectively, is needed in combination with an ion source (assist source), the ion source being operated with a mixture of argon and nitrogen. For the generation of nitrides, oxides, oxynitrides or hydronitrides it is also possible to use the corresponding gas mixtures. The refractive index and the extinction coefficient of each a-Si:H:x or Ge:H:x layer of the optical layer system are adjusted by the establishment of the absolute gas flow and/or of the ratios of the partial gas flows in the respective gas mixture in the ion source and also of the powers of the evaporator and/or of the ion source. It is possible accordingly for each layer to adjust the stoichiometry and so to control the optical behavior. The aim is typically for substrate temperatures of 100° C.-300° C., preferably 140° C.-240° C.

In prior trials, the optimal process parameters for the respective arrangement of evaporator, substrate and ion source are determined for a layer with high, low or middle refractive index. Using these known data it is then possible to deposit layers of the optical layer system.

In one embodiment of the method of the invention the optimal process parameters of a selected coating method for adjusting a defined/desired refractive index and extinction coefficient of each a-Si:H:x or Ge:H:x layer of the layer system are ascertained experimentally by prior trials or simulations.

The object of the present invention is also achieved by an optical layer system according to independent claim 8 of the patent.

In the optical layer system of the invention, produced by a method as claimed in any of claims 1 to 7, the multiplicity of layers are formed of an identical material, where the high-, mid- and low-index layers differ only in their stoichiometry of a doping gas and where the optical properties of the high-, mid- and low-index layers are adjustable by the stoichiometry of the doping gas by means of a process controller.

In one variant of the optical layer system of the invention, the layer system has two or more layers having a middle refractive index nay, where y is an integer greater than zero and where n_{H}>n_{M1}≥n_{M2}≥ . . . ≥n_{My}>n_{L}. In other words, the layer system may comprise two or more layers which have a middle refractive index, where the mid-index layers have different refractive indices in relation to the high- and low-index layers, the indices lying between the high-index and low-index layers. The mid-index layers may in turn have partially identical and/or different refractive indices among one another.

The layer system of the invention may therefore be formed not only of layers which only have a high-index or low-index refractive index. The layers of the layer system may also have high-, mid- and low-index refractive indices or the layer system may be formed of layers which feature a layer having a high refractive index, more than one layer having a middle refractive index, and a layer having a low refractive index, where the refractive indices of the mid-index layers may be partly identical or different.

The use of the same chemical elements in all layers of the optical layer system has the advantage that there is no need for long purging processes between the individual layer deposition steps, since there is no need to switch between different coating materials. As a result there is also a drastic reduction in the process times and a high quantity can be realized.

In one preferred variant of the optical layer system of the invention, the identical material is hydrogenated amorphous silicon (a-Si:H) or hydrogenated germanium (Ge:H) and the doping gas is hydrogen (H₂).

Hydrogenated amorphous silicon possesses the eminent advantage that depending on the stoichiometry of the hydrogen incorporated, the refractive index can be adjusted within a wide range. The use of hydrogenated silicon (Si:H) for layers of high refractive index in optical filters is described by Lairson et al. in an article with the title “Reduced Angle-shift Infrared Bandpass Filter Coatings” (Proceedings of the SPIE, 2007, vol. 6545, pp. 65451C-1-65451C-5) and by Gibbons et al. in an article with the title “Development and implementation of a hydrogenated a-Si reactive sputter deposition process” (Proceedings of the Annual Technical Conference, Society of Vacuum Coaters, 2007, vol. 50, pp. 327-330).

In one preferred variant of the optical layer system of the invention the optical layer system is formed as a bandpass filter.

A bandpass filter which consists of a layer sequence of high-, mid- and/or low-index layers preferably has for a high-index layer of a-Si:H a refractive index n_{N}=3.35 to 3.8 and an extinction coefficient k<0.001, for a mid-index layer a refractive index n_{M}=3.0 to 3.6 with k<0.001 and for a low-index layer a refractive index of n_{L}=2.5 to 3.3 with k<0.001 for a wavelength range from 800 nm to 1100 nm.

In another preferred variant, the bandpass filter, which consists of a layer sequence of high-, mid- and/or low-index layers, has for a high-index layer of a-Si:H:x a refractive index n_{H}=3.6 to 3.8 and an extinction coefficient k<0.0001, a mid-index layer has a refractive index n_{M}=3.2 to 3.3 with k<0.0001 and a low-index layer has a refractive index n_{L}=3.0 to 3.1 with k<0.001 for a wavelength range from 800 nm to 1100 nm.

Where the optical layer system of the invention is formed as a bandpass filter, the optical bandpass filter preferably comprises at least two mid-index or low-index cavity layers having a refractive index nm or n_{L} with a respective thickness of 10 nm to 3000 nm, and also at least five layer stacks each formed of alternately stacked low-index and high-index layers having a refractive index n_{L} or n_{M}, respectively, with a respective thickness of 5 to 200 nm.

The high-, mid- or low-index layers form in each case the cavities in the bandpass filter, in other words in a region in which there is constructive interference of the incidence radiation, thereby generating a region of high transmission of the optical filter. Through the number of cavities formed in the optical filter it is possible to precisely establish the transmittance and the width of the pass band of the filter. Through the choice of the refractive indices in combination with the layer thickness of the cavities it is possible to reduce the wavelength shift of the pass band of the optical bandpass filter. In other words, for different incident angles of the incident radiation, the filter properties present are virtually the same.

As well as the cavities, the layer system comprises layer stacks, which act as mirror layers and form stop bands of the filter. The greater the number of layer stacks present in the optical bandpass filter with corresponding thicknesses, the more effectively the incident radiation is reduced in this region by means of destructive interference.

In a further variant of the optical layer system, the optical layer system comprises not only a high-index layer of a-Si:H:x or a-Ge:H:x and a low-index layer of a-Si:H:x or a-Ge:H:x but also a further layer of Si₃N₄ or SiO₂. A layer system of this kind has the advantage that the spectrum of possible refractive indices is extended, in particular to include low refractive indices in the case of SiO₂; SiO₂ has a refractive index of 1.4 to 1.47 in the wavelength range above 800 nm. In the case of Si₃N₄, which in comparison to a-Si:H and SiO₂ constitutes a material of mid-index refractive index—Si₃N₄ has a refractive index of 2 to 2.1 in the wavelength range above 800 nm—the possibility exists of more precisely adapting the optical parameters of the filter.

In one variant of the optical layer system the optical layer system is formed as a Rugate filter, where via the multiplicity of layers a refractive index gradient can be formed which is adjustable by the stoichiometry of the doping gas or of the doping gases via the process controller for each layer of the multiplicity of layers.

In process terms, this preferred variant forms a so-called quasi-Rugate filter within the individual mirror systems, with a mirror system in the sense of the invention referring to the construction of an interference filter composed of the high-, mid- and/or low-index layers and of the cavities formed. A Rugate filter is a dielectric mirror which selectively reflects a defined wavelength range of light. This effect is achieved through a periodic, constant or quasi-discrete change in the refractive index as a function of the thickness of the mirror. A defined wavelength fraction of the light is unable to propagate in the Rugate filter, and is reflected. A particular challenge here is the realization of the constant or quasi-discrete refractive index profile. This profile is established through the chemical composition of the multiplicity of filter layers as a function of the layer thickness. This is achievable through a continuous change in the gas composition during the deposition processes for the individual filter layers, where a dynamic process controller adjusts the stoichiometry of the doping gas into the filter material to be deposited and so forms different refractive indices.

In another variant of the optical layer system, the optical layer system is formed as an optical interference filter.

The optical interference filter preferably has a transmission range of 420 nm to 2800 nm, more preferably 800 nm to 1100 nm. The width of the pass band is preferably to 50 nm at 50% transmission. The edge steepness between 10% and 90% transmission is preferably between 8 and 20 nm. The transmission of the stop bands is preferably less than 1% transmission, preferably less than 0.1% transmission, but better still less than 0.01% transmission in the range from 400 to 910 nm and in the 970 to 1100 nm range.

These wavelength ranges of the pass bands and of the stop bands are determined by the thickness of the individual layers of the filter. Specifically, the width of the pass band is adjusted by the number of cavities in conjunction with their refractive indices and their layer thickness.

The ultimate design of an optical filter is dependent on the requirements, which are determined by the subsequent use for example within a sensor. Particular requirements are imposed here on the pass band and the stop bands. These target values allow layer stack sequences to be ascertained, using optical models, from the multiplicity of layers of the optical layer system. The thickness of the individual layers, the number, arrangement and thickness of mirror layers and cavities therefore determine the optical behavior of the filter.

The region in the near infrared from 800 to 1100 nm is of particular interest for applications of the filters in sensors which use the time-of-flight (ToF) method to be able to determine distances and so to generate three-dimensional image information. This plays a major part in modern future-oriented technologies such as LIDAR (Light detection and ranging), which is needed for autonomous driving, or in human-machine interactions, for example in the recognition of gestures or faces by portable terminal devices.

The intention of the text below is to illustrate the invention in more detail, using exemplary embodiments.

### IN THE ASSOCIATED DRAWINGS

FIG. 1 shows an embodiment of the optical layer system of the invention as an optical interference filter, with 4 different filter examples (a-d);

FIG. 2 shows an illustrative transmission range of the interference filter of the invention from FIG. 1;

FIG. 3 shows a schematic representation of a sputter process for producing the optical layer system of the invention;

FIG. 4 shows a use example of the optical layer system of the invention as a ToF sensor for facial recognition.

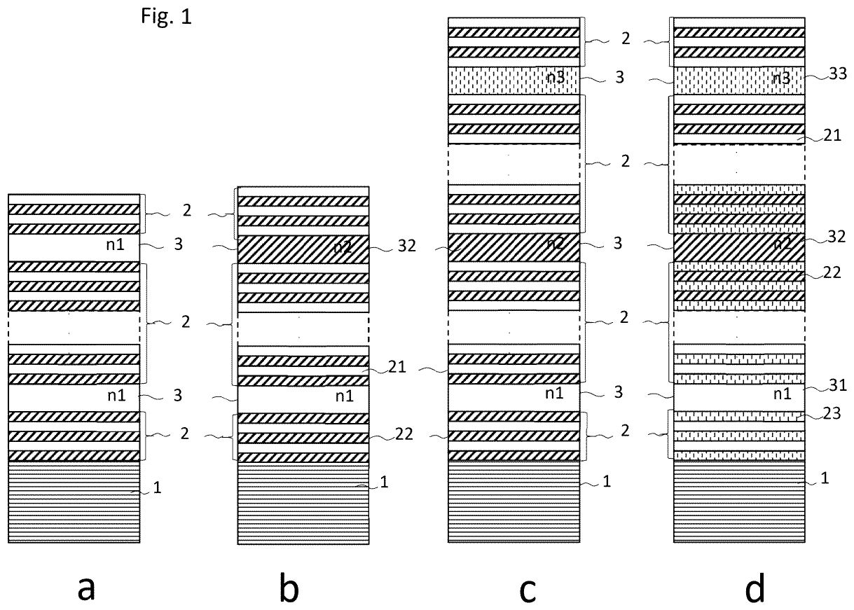

FIG. 1 shows an embodiment of the optical layer system of the invention as an optical interference filter. The optical interference filter is deposited on a substrate 1. The deposition may take place, for example, by means of a sputter process, a CVD process or an evaporation process (e-beam). The interference filter consists in general of a multiplicity of layers which have different refractive indices and also extinction coefficients. The multiplicity of layers form layer stacks, with cavities and mirror systems alternating. The mirror systems are constructed in turn of different mirror layers, or stacked, and in general there is an alternation of high-, low- and/or mid-index layers. The optical thickness of a cavity corresponds to λ/4, that of the mirror layers to λ/2.

FIG. 1a) shows a filter example with two cavities 3 and mirror systems 2 of a-Si:H. The two cavities 3 have an identical refractive index n₁, e.g., n₁=3.1, and the mirror systems 2 have two different refractive indices 21, 22, e.g., n₁=3.1 and n₂=3.6.

FIG. 1b) shows a filter example having two cavities 3 and mirror systems 2 of a-Si:H. The two cavities 3 have different refractive indices n₁ 31 and n₂ 32, e.g., n₁=3.1 and n₁=3.6. The mirror layers 21, 22 of the mirror systems likewise have different refractive indices, e.g., n₁=3.1 and n₂=3.6.

FIG. 1c) shows a filter example having three cavities 3 and mirror systems 2 of a-Si:H. The three cavities 3 have different refractive indices n₁ 31, n₂ 32 and n₃ 33, e.g., n₁=3.6, n₂=3.2 and n₃=3.1. The mirror layers 21, 22 of the mirror systems likewise have identical refractive indices, e.g., n₁=3.1 and n₂=3.6.

FIG. 1d) shows a filter example having three cavities 3 and mirror systems 2 of a-Si:H. The three cavities 3 have different refractive indices n₁ 31, n₂ 32 and n₃ 33, e.g., n₁=3.6, n₂=3.2 and n₃=3.1. The mirror layers 21, 22, 23 of the mirror systems likewise have different refractive indices, e.g., n₁=3.6, n₂=3.2 and n₃=3.1.

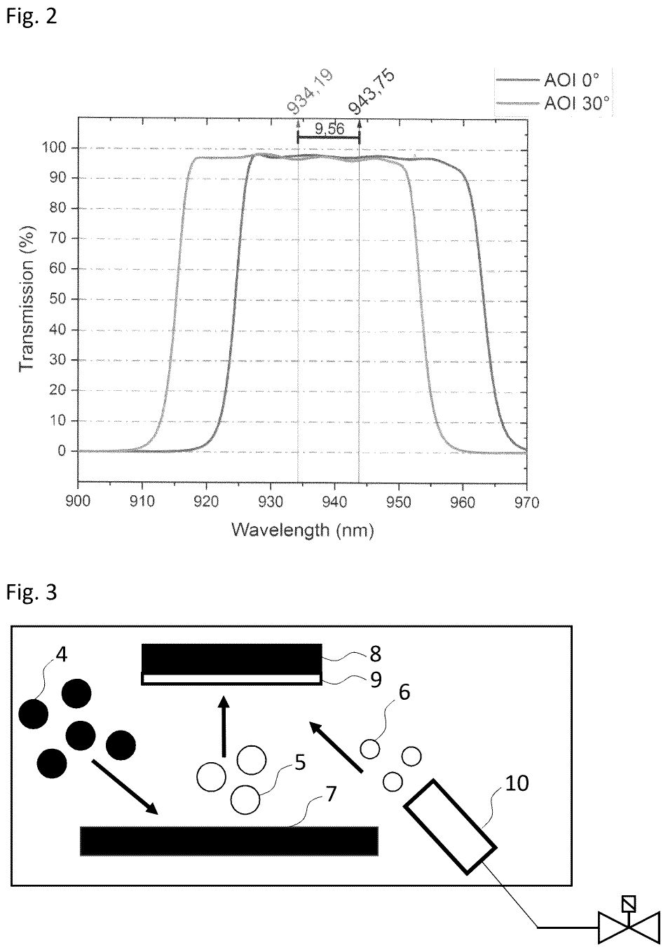

FIG. 2 shows an illustrative transmission range of the interference filter of the invention from FIG. 1. As a result of the exclusive use of a-Si:H, the effective refractive index of the filter is higher than when using a material of low refractive index, such as SiO2, for example. The shift in the transmission band is inversely proportional to the effective refractive index. In other words, a high effective refractive index results in a smaller shift in the transmission band.

FIG. 3 shows the schematic representation of a sputter process for producing the optical layer system of the invention.

In the course of the sputter deposition, energetic particles are directed onto a silicon target 7, with these particles having sufficient energy to sputter out silicon atoms from the target 7 and, under the influence of a magnetic or electrical field, to transfer them to the surface of the substrate 1, which is thereby coated. The sputter gas may be, for example, argon (Ar) from an argon source. The sputter gas used may alternatively comprise other inert gases that can be ionized as well, such as xenon, for example.

A further production variant entails the use of a plasma source and/or ion source 10 for establishing the reactive gas content 6 within the non-reactively or only part-reactively sputtered layer. Following the deposition of a lamina of subnanometer thickness, the sputtered layer is retrospectively treated by means of the plasma source and/or ion source 10 in each case, in order to establish the desired stoichiometry.

In order to produce hydrogenated amorphous silicon, hydrogen is admitted to the process chamber via a gas inlet during the sputter deposition process. Dynamic flow regulators make it possible to adjust the gas quantity of sputter gas and hydrogen or, if desired, of the other doping gases. Accordingly it is possible to adjust and regulate the desired stoichiometry of the doping gases for the production of low-, mid- and high-index layers, in order to ensure the development of identical optical properties during a gas flow change between the low-, mid- and high-index layers. By means of the process parameters such as the substrate temperature, the target bias voltage (−V), the process chamber pressure, the total flow rate, etc., it is likewise possible to influence and regulate the incorporation of hydrogen into the silicon.

The layer materials thus generated are deposited on the substrate in a layer thickness and sequence determined beforehand by means of optical models, in order to meet the optical requirements, for an optical filter, for example. The precise knowledge of the dependency relationships between the optical properties (refractive index and extinction coefficient) of the individual layers and the process parameters is an important prerequisite for being able to make correct predictions for the properties, of an optical filter, for example, with previously used models for the simulation of an optical layer system to be produced. For each high-, low- or mid-index layer, the process parameters (process pressure, gas flow, gas ratio, powers of the sputter source/plasma source and/or ion source, temperature) are adjusted exactly and so reproducible layer properties can be attained.

The method of the invention does away with switching between different sputter materials, such as niobium pentoxide or silicon dioxide, for example, or the admission of different doping gases, such as oxygen or hydrogen, for example, for the layers having different refractive indices. This also does away with long purge times in the process chamber, allowing the productivity to be boosted and the layer properties to be improved. This is especially of interest when the end products produced are needed in large quantity.

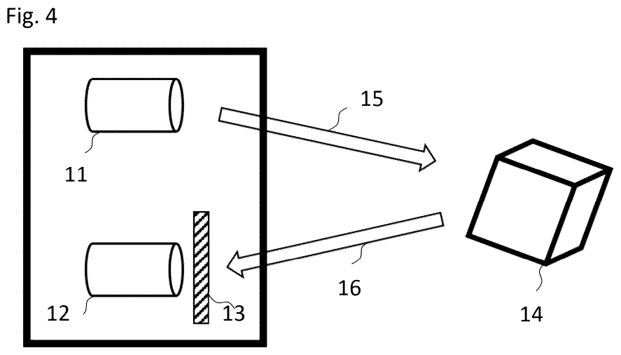

FIG. 4 shows a use example of the optical layer of the invention as a ToF sensor for facial recognition. The ToF sensor consists of a light source 11, typically a laser. This source emits light 15, which is reflected by a three-dimensional object 14. The reflected light 16 is detected by a photodetector 12. It is advantageous for an optical filter 13 in the form of a bandpass filter to be arranged in front of the photodetector 12. This filter ensures that only radiation having a wavelength which is emitted by the light source is detected and processed. For the optical functionality of the filter 13, it must have a high transmission in the pass band and a very low transmission outside the pass band. It is important, moreover, that the filter has a high tolerance in relation to the wavelength shift at different incident angles of the light. These requirements must form part of the filter design process.

### Method for Producing an Optical Layer System, and an Optical Layer System Produced Therewith

### LIST OF REFERENCE SYMBOLS

1 substrate
2 mirror layer
   21 first mirror layer with refractive index n₁
   22 second mirror layer with refractive index n₂
   23 third mirror layer with refractive index n₃
3 cavity
   31 first cavity with refractive index n₁
   32 second cavity with refractive index n₂
   32 third cavity with refractive index n₃
4 sputter gas
sputtered particles
6 reactive gas
7 sputter target
8 substrate
9 coating
plasma source and/or ion source
11 light source
12 photodetector
13 optical filter
14 three-dimensional object
15 emitted light of the light source
16 reflected light of the light source

1. A method for producing an optical layer system consisting of a multiplicity of layers, where the layers of the optical layer system are deposited onto a substrate by a selected coating method from an identical material which is hydrogenated amorphous silicon, a-Si:H, or hydrogenated germanium, Ge:H, and where a refractive index and an extinction coefficient of each layer of the multiplicity of layers of the layer system are adjusted by a regulation of process parameters of the selected coating method.

2. The method for producing an optical layer system as claimed in claim 1, where the identical material is a Si:H:x or Ge:H:x, where x comprises nitrogen (N₂) or chlorine (Cl₂).

3. The method for producing an optical layer system as claimed in claim 1, where the coating method is a sputtering process, where the sputtering process takes place either reactively by a reactive gas mixture of argon, Ar, and/or krypton, Kr, and/or helium, He, and/or xenon, Xe, and hydrogen, H, and/or nitrogen and/or chlorine, or the sputtering takes place by Ar, Kr, He and/or Xe and the layers of the layer system are hydrogenated to a-Si:H or Ge:H by a plasma source and/or ion source, or the sputtering process is carried out as a combination of reactive sputtering and of the plasma source and/or ion source used, where the refractive index and the extinction coefficient of each individual a-Si:H or Ge:H layer of the layer system are adjusted via a ratio of hydrogen to Ar, Kr, He and/or Xe.

4. The method for producing an optical layer system as claimed in claim 1, where the reactive gas mixture is argon, Ar, and nitrogen, N, or argon, Ar and oxygen, O₂.

5. The method for producing an optical layer system as claimed in claim 1, where the coating method is a chemical vapor deposition process, CVD process, where the CVD process takes place either with plasma enhancement or catalytically or thermally by an evaporator unit and a plasma source, where the refractive index and the extinction coefficient of each a-Si:H:x or Ge:H:x layer of the layer system are adjusted by a gas flow regulation via a ratio of silane or germane and hydrogen and/or of a power of the evaporator unit and the plasma source.

6. The method for producing an optical layer system as claimed in claim 1, where the coating method is an electron beam evaporation process in conjunction with an ion source, where the refractive index and the extinction coefficient of each a-Si:H:x or Ge:H:x layer of the layer system are adjusted by an establishment of an absolute gas flow and/or a ratio of partial gas flows in a gas mixture of the ion source and of a power of an evaporator unit and the ion source.

7. The method for producing an optical layer system as claimed in claim 2, where the optimum process parameters for adjusting a defined refractive index and extinction coefficient of each a-Si:H or Ge:H layer of the layer system are ascertained experimentally by prior trials or simulations.

8. An optical layer system which is produced according to of the method as claimed in claim 1, comprising a multiplicity of layers arranged on a substrate, where one part of the layers has a high refractive index n_{H} and another part of the layers has a low refractive index n_{L} and also a further part of the layers has a middle refractive index n_{M}, where n_{H}>n_{M}≥n_{L}, where the layers having different refractive indices have an alternating stacked arrangement, wherein the multiplicity of layers are formed of an identical material, where the high-, mid- and low-index layers differ only in their stoichiometry of a doping gas and where the optical properties of the high-, mid- and low-index layers are adjustable by the stoichiometry of the doping gas by a process controller.

9. The optical layer system as claimed in claim 8, wherein the layer system has two or more layers having a mid-index refractive index nMy, where y is an integer greater than zero and where n_{H}>n_{M1}≥n_{M2}≥ . . . ≥n_{My}>n_{L}.

10. The optical layer system as claimed in claim 8, wherein the identical material is hydrogenated amorphous silicon, a-Si:H, or hydrogenated germanium, Ge:H, and the doping gas is hydrogen, H.

11. The optical layer system as claimed in claim 1, wherein the optical layer system is formed as a bandpass filter.

12. The optical layer system as claimed in claim 11, wherein the bandpass filter consists of a layer sequence of high-, mid- and/or low-index layers, where a high-index layer of a-Si:H has a refractive index n_{H}=3.35 to 3.8 and an extinction coefficient k<0.001, a mid-index layer has a refractive index n_{M}=3.0 to 3.6 with k<0.001 and a low-index layer has a refractive index n_{L}=2.5 to 3.3 with k<0.001 for a wavelength range from 800 nm to 1100 nm.

13. The optical layer system as claimed in claim 10, wherein the bandpass filter consists of a layer sequence of high-, mid- and/or low-index layers, where a high-index layer of a-Si:H has a refractive index n₁=3.6 to 3.8 and an extinction coefficient k<0.0001, a mid-index layer has a refractive index n_{M}=3.2 to 3.3 with k<0.0001 and a low-index layer has a refractive index n_{L}=3.0 to 3.1 with k<0.0001 for a wavelength range from 900 nm to 980 nm.

14. The optical layer system as claimed in claim 1, wherein the optical layer system is formed as a Rugate filter, where via the multiplicity of layers a refractive index gradient can be formed which is adjustable by the stoichiometry of the doping gas via the process controller for each layer of the multiplicity of layers of the optical layer system.

15. The optical layer system as claimed in claim 8, wherein the optical layer system is formed as an optical interference filter.
